(19) United States
(12) Patent Application Publication
(10) Pub. No.: US 2016/0108547 A1
(43) Pub. Date: Apr. 21, 2016

(54) METHOD FOR OBTAINING MONOCRYSTALLINE GALLIUM-CONTAINING NITRIDE AND MONOCRYSTALLINE GALLIUM-CONTAINING NITRIDE OBTAINED BY THIS METHOD

(71) Applicant: AMMONO S.A., Warszawa (PL)

(72) Inventors: Roman DORADZINSKI, Warszawa (PL); Marcin ZAJAC, Garwolin (PL); Robert KUCHARSKI, Warszawa (PL)

(21) Appl. No.: 14/894,337

(22) PCT Filed: Mar. 24, 2014
(86) PCT No.: PCT/EP2014/055876

§ 371 Date: Nov. 25, 2015

(30) Foreign Application Priority Data
May 30, 2013 (PL) P.404149

(51) Int. Cl. C30B 7/10; H01B 1/02; C30B 29/40

(52) U.S. Cl. CPC C30B 7/105; C30B 29/406; H01B 1/02

(57) ABSTRACT

The object of the invention is a method for obtaining monocrystalline gallium-containing nitride, from gallium-containing feedstock in the environment of supercritical ammonia-containing solvent with the addition of a mineraliser, containing an element of Group I (IUPAC, 1989), wherein, in an autoclave, two temperature zones are generated, i.e. a dissolution zone of lower temperature, containing feedstock, and, below it, a crystallisation zone of higher temperature, containing at least one seed, a dissolution process of the feedstock and a crystallisation process of the gallium-containing nitride on the at least one seed are carried out, characterised in that at least two additional components are introduced into the process environment, namely:
a) an oxygen getter in a molar ratio to ammonia ranging from 0.0001 to 0.2,
b) an acceptor dopant in a molar ratio to ammonia not higher than 0.001.

The invention also includes monocrystalline gallium-containing nitride, obtained by this method.

### RELATED APPLICATIONS

This application is the U.S. National Phase of and claims priority to International Patent Application No. PCT/EP2014/055876, International Filing Date Mar. 24, 2014, entitled METHOD FOR OBTAINING MONOCRYSTALLINE GALLIUM-CONTAINING NITRIDE AND MONOCRYSTALLINE GALLIUM-CONTAINING NITRIDE OBTAINED BY THIS METHOD, which claims priority to, and benefit of, Polish Application No. P.404149, filed May 30, 2013; all of which are incorporated herein by reference in their entireties.

### FIELD OF THE INVENTION

The object of the invention is a method for obtaining monocrystalline gallium-containing nitride. The invention also includes monocrystalline gallium-containing nitride obtained by this method.

### BACKGROUND OF THE INVENTION

From the international patent application No. WO 02/101120 A2, a method for obtaining bulk monocrystalline gallium-containing nitride, and in particular gallium nitride, GaN, by its recrystallization in a supercritical ammonia solution, containing a mineraliser, is known. Document WO 02/101120 A2 comprehensively and exhaustively describes construction of a reactor (high-pressure autoclave) used in this process, as well as an appropriate feedstock, seed, a mineraliser and a temperature-pressure course of the process. The key information disclosed in WO 02/101120 A2 is that gallium nitride has, under these conditions, a negative temperature coefficient of solubility. This means that its solubility decreases along with an increase in temperature. Consequently, in an autoclave, a feedstock is placed above seed, and in recrystallization stage, in the seed zone, a temperature higher than the temperature in the zone, in which the feedstock is located, is maintained. The result of the process conducted this way is dissolution of feedstock and growth of monocrystalline GaN on seed. WO 02/101120 A2 does not mention the use of a metal of Group II (IUPAC, 1989), i.e. an alkali earth metal, and in particular calcium, as an additive for mineraliser or as the mineraliser itself. Mg and Zn are indicated as possible doping elements. Electrical properties of the obtained nitride monocrystals are not described.

The Polish patent application No. P-357706 discloses a complex mineraliser, in the form of alkali metal and alkali earth metal (for example calcium and magnesium are mentioned), used in a molar ratio of 1:500 to 1:5 in relation to alkali metal. The application mentions the possibility of doping the material, but does not specify the amount of particular dopants. Electrical properties of the obtained nitride monocrystals are not described.

In turn, the Polish patent application No. P-357700 discloses a complex mineraliser, in the form of alkali metal and acceptor dopant (for example magnesium, zinc and cadmium are mentioned). The amount of acceptor dopant in relation to the alkali metal or ammonia are generally not specified at the same time. In an embodiment, an admixture in the form of magnesium, used in a molar ratio of 0.05 to the main mineraliser, i.e. to potassium, is disclosed. The application does not mention explicitly the use of calcium in combination with alkali metal as a mineraliser. Electrical properties of the obtained nitride monocrystals are not described.

In the international patent application No. WO 2004/053206 A1, the possibility of using a complex mineraliser, in the form of alkali metal and alkali earth metal, and preferably calcium or magnesium, or in the form of alkali metal and acceptor dopant, such as magnesium, zinc or cadmium, is described again. However, the simultaneous use of alkali metal, calcium and acceptor dopant is not disclosed. Electrical properties of the obtained nitride monocrystals are not described.

The international application No. WO 2005/122232 A1 discloses the use of 0.05 g of Zn or 0.02 g of Mg as an admixture to feedstock which is metallic gallium. This means, that under the process conditions, the molar ratio of Mg or Zn to ammonia, 240 g of which was used, i.e. about 14 mol, is of the order of 10⁻⁵. Thereby—according to WO 2005/122232 A1—a compensated (semi-insulating) material with a resistivity of about 10⁶ Ω cm is obtained. The application does not disclose the use of calcium (or any other oxygen getter) as an admixture to mineraliser. The problem of oxygen content in the crystals obtained is not addressed.

Finally, European application No. EP 2267197 A1, in order to control electrical properties of gallium nitride, and in particular to obtain a compensated (semi-insulating) material, requires to use a mineraliser in the form of alkali metal, and simultaneously with it - an acceptor dopant, specifically magnesium, zinc or manganese, in a molar ratio of at least 0.0001, and most preferably at least 0.001, in relation to ammonia. In case of using zinc or magnesium, p-type material is obtained directly after the process. Only after additional heat treatment (annealing), it becomes a semi-insulating material. In case of using manganese—a semi-insulating material can be obtained directly after the process. The application does not disclose the use of calcium (or any other oxygen getter) as an admixture to mineraliser. The problem of oxygen content in the crystals obtained is not addressed.

### DETAILED DESCRIPTION OF THE PREFERRED EMBODIMENTS

So far, it has not been disclosed or suggested, that in this method for obtaining gallium-containing nitride, simultaneously with a mineraliser in the form of alkali metal (metal of Group I, IUPAC, 1989), in a molar ratio of 1:200 to 1:2 in relation to ammonia, i.e. according to the disclosure of the aforementioned patent applications, to introduce to the process environment, at least two additional components, namely:
a)an oxygen getter in the form of calcium or rare earth element or a combination thereof, in a total molar ratio to ammonia ranging from 0.0001 to 0.2 and
b) acceptor dopants in the form of magnesium, zinc, cadmium, or beryllium, or combinations thereof, in a total molar ratio to ammonia not higher than 0.001. GaN monocrystals, having been obtained so far without the use of the aforementioned getter and acceptor dopant, are characterised by the concentration of oxygen (unintentionally introduced into the growth environment) at the level of 2×10¹⁹ cm⁻³ (F. Tuomisto, J.-M. Maki, M. Zajac, Vacancy defects in bulk ammonothermal GaN crystals, J. Crystal Growth, 312, 2620 (2010)). Oxygen, present in crystallographic lattice, plays the role of a donor, providing free electrons of similar concentration—in the order of 2×10¹⁹ cm⁻³ or slightly lower (Tuomisto et al.), which makes the considered material highly conductive, with n-type conductivity type. In turn, introduction of the acceptor dopant alone does not change the concentration of oxygen, but allows to change the type of conductivity to p-type, and after appropriate heat treatment, a semi-insulating material with a resistivity of the order of 10¹¹ Ω cm can be obtained (patent application EP 2267197 A1). At the same time, Mg acceptor is present therein at the level of up to about 4×10¹⁹ cm⁻³ (FIG. 2 in application EP 2267197 A1). For a material with a p-type conductivity, by manipulating the concentration of Mg, resistivity and concentration of free holes can be controlled: for the molar ratio of Mg : NH₃=0.0001: concentration of holes about 1×10¹⁸ cm⁻³, resistivity 9×10² Ω cm; for the molar ratio of Mg:NH₃=0.00025: 5×10¹⁸ cm⁻³ and 8 Ω cm, respectively; for the ratio of Mg:NH₃=0.001: 1×10¹⁹ cm⁻³ and 1.7 Ω cm, respectively (Examples 1-4 in application EP 2267197 A1).

Surprisingly, it has been found that simultaneous use of calcium or a rare earth element (or a combination thereof) and an acceptor dopant (or acceptor dopants) provides an advantageous combination of two phenomena. On one hand, it allows to effectively remove oxygen from the obtained crystal, namely, by manipulating the amount of calcium, the concentration of oxygen in the crystal can be continuously changed in the range of about 10¹⁹ cm³ to about 10¹⁸ cm³. In turn, in the case of rare earth elements—in a wide range of their contents in the reaction environment—a monocrystal with a low oxygen concentration of about 10¹⁸ cm³ and less is obtained. On the other hand, acceptor dopants , which are very efficiently incorporated in the obtained monocrystal, compensate the unintentional donors (oxygen), which allows to control electrical properties of the crystal. It appears that, by simultaneously introducing oxygen getters and acceptor dopants into the process environment and by manipulating their composition (relative proportions) and their type, GaN monocrystals of desired electrical parameters (p-type, n-type, semi-insulating material (compensated)) but of higher purity, i.e. of lower concentrations of oxygen and acceptor than those given in EP 2267197 A1, can be obtained. In particular, in order to obtain GaN monocrystals having similar electrical characteristics as in the cited patent application, acceptor dopant is used in the process in a molar ratio (to ammonia) of one or two orders of magnitude lower than in EP 2267197 A1. In a particular case, a material ideally compensated with acceptors, having a very high electrical resistivity, higher than 10⁶ Ω cm, is obtained.

The individual aforementioned components, according to the present invention, can be introduced into the process environment in the elemental (metal) form, as well as in the form of various compounds, such as e.g. azides, amides, imides, amidoimides, hydrides, etc.

These components can be introduced into the environment separately or in combination, wherein in the latter case mixtures of elements or compounds, as well as intermetallic compounds and alloys, can be used. Preferably, but not necessarily, components are introduced into the process environment together with a mineraliser, or in other words a complex mineraliser which, in addition to an alkali metal, contains also the aforementioned oxygen getter and acceptor dopant, is used.

Therefore, it is an object of the present invention to propose a method for obtaining monocrystalline gallium-containing nitride having a reduced oxygen content and desired electrical properties as a result of the use of an oxygen getter and of the simultaneous compensation of unintentional donors (mainly oxygen) with acceptors.

Another object of the invention is to provide such a nitride.

A method for obtaining monocrystalline gallium-containing nitride from gallium-containing feedstock, in the environment of supercritical ammonia-containing solvent with the addition of a mineraliser, containing an element of Group I (IUPAC, 1989), wherein, in an autoclave, two temperature zones are generated, i.e. a dissolution zone of lower temperature, containing feedstock, and, below it, a crystallisation zone of higher temperature, containing at least one seed, a dissolution process of the feedstock and a crystallisation process of the gallium-containing nitride on the at least one seed are carried out, according to the invention is characterised in that at least two additional components are introduced into the process environment, namely:
a)an oxygen getter in a molar ratio to ammonia ranging from 0.0001 to 0.2,
b)an acceptor dopant in a molar ratio to ammonia not higher than 0.001.

Preferably, the oxygen getter is introduced in a molar ratio to ammonia ranging from 0.0005 to 0.05.

Preferably, the oxygen getter is constituted by calcium or a rare earth element, preferably gadolinium or yttrium, or a combination (mixture) thereof.

Preferably, the acceptor dopant is constituted by magnesium, zinc, cadmium or beryllium, or a combination (mixture) thereof.

Preferably, the oxygen getter and the acceptor dopant are introduced in the elemental for, i.e. in the form of metal, or in the form of compound, preferably from the group comprising azides, amides, imides, amidoimides and hydrides, wherein these components are introduced separately or in combination, and in the latter case mixtures of elements or compounds, intermetallic compounds or alloys, being used.

Preferably, the oxygen getter and/or the acceptor dopant are introduced into the process environment together with the mineraliser.

Preferably, the mineraliser contains sodium or potassium, in a molar ratio to ammonia ranging from 0.005 to 0.5.

In a particularly preferred embodiment of the invention, a stoichiometric gallium nitride, GaN, is obtained.

Preferably, the method according to the invention is carried out in an autoclave having a volume higher than 600 cm³, more preferably higher than 9000 cm³.

The invention also includes monocrystalline gallium-containing nitride obtained by the above method, containing at least one element of Group I (IUPAC, 1989) in an amount of at least 0.1 ppm, and characterised in that it comprises oxygen at a concentration not higher than 1×10¹⁹ cm⁻³, preferably not higher than 3×10¹⁸ cm⁻³, and most preferably not higher than 1×10¹⁸ cm⁻³.

In a first preferred embodiment, nitride of the invention is an n-type conductive material.

In this case, it contains acceptors selected from magnesium, zinc, cadmium or beryllium with a total concentration not higher than 1×10¹⁸ cm⁻³, more preferably not higher than 3×10¹⁷ cm⁻³, most preferably not higher than 1×10¹⁷ cm⁻³, wherein the ratio of oxygen concentration to the total concentration of acceptors being not lower than 1.2.

Preferably, as an n-type material, nitride of the invention exhibits a concentration of carriers (free electrons) not higher than 7×10¹⁸ cm, more preferably not higher than 2×10^{18 -3} cm, and most preferably not higher than 7×10¹⁷ cm⁻³.

In a second preferred embodiment, nitride of the invention is a p-type conductive material.

In this case, it contains acceptors selected from magnesium, zinc, cadmium or beryllium with a total concentration not higher than 2×10¹⁹ cm⁻³, more preferably not higher than 6×10¹⁸ cm⁻³, most preferably not higher than 2×10¹⁸ cm⁻³, the ratio of oxygen concentration to the total concentration of acceptors being not higher than 0.5.

Preferably, as a p-type material, nitride of the invention exhibits a concentration of carriers (free holes) lower than 5×10¹⁷ cm⁻³.

In a third preferred embodiment, nitride of the invention is a highly resistive (semi-insulating) material.

In this case, it contains acceptors selected from magnesium, zinc, cadmium or beryllium with a total concentration not higher than 1×10¹⁹ cm⁻³, more preferably not higher than 3×10¹⁸ cm⁻³, most preferably not higher than 1×10¹⁸ cm⁻³, wherein the ratio of oxygen concentration to the total concentration of acceptors ranging from 0.5 to 1.2.

Preferably, as a highly resistive (semi-insulating) material, nitride of the invention has a resistivity higher than 1×10⁵ Ω cm, more preferably higher than 1×10⁶ Ω cm, and most preferably higher than 1×10⁹ Ω cm.

In a particularly preferred embodiment of the invention, nitride of the invention is a stoichiometric gallium nitride, GaN.

The gallium-containing nitride is a chemical compound having in its structure at least a gallium atom and a nitrogen atom. It is therefore at least a two-component compound GaN, a three-component compound AlGaN, InGaN and a four-component compound AlInGaN, preferably containing a substantial amount of gallium at a level higher than the doping level. The composition of other elements with respect to gallium, in the structure of this compound, can be varied to an extent which does not interfere with the ammonia alkaline nature of the crystallisation technique.

The gallium-containing feedstock is gallium-containing nitride or its precursor. As the feedstock, a metallic gallium, GaN obtained by flux methods, HNP method, HVPE method, or a polycrystalline GaN obtained from metallic gallium as a result of reaction in a supercritical ammonia-containing solvent.

The mineraliser is a substance which provides, in the supercritical ammonia-containing solvent, one or more types of ions of alkali metals, and supports dissolution of the feedstock (and gallium-containing nitride).

The supercritical ammonia-containing solvent is a supercritical solvent, consisting at least of ammonia in which one or more types of alkali metal ions are contained, the said ions supporting dissolution of gallium-containing nitride. The supercritical ammonia-containing solvent may also contain derivatives of ammonia and/or their mixtures, in particular hydrazine.

### Example 1

Obtaining of doped GaN (Ca:NH₃=0.0005, Mg:NH₃=0.000005, Na:NH₃=0.04)

In a high-pressure autoclave with a volume of 600 cm³, in a dissolution zone, as the feedstock, 107.8 g (about 1.3 mol) of polycrystalline GaN with the addition of 0.22 g of Ca (5.6 mmol) and 1.3 mg of Mg (0.05 mmol) was placed. Into the autoclave, 10.34 g (about 449 mmol) of metallic sodium having a purity of 4N was also introduced.

As the seed, 18 plates of monocrystalline gallium nitride obtained by HVPE method or by crystallisation from supercritical ammonia-containing solution, oriented perpendicularly to c-axis of monocrystal, with a diameter of about 25 mm (1 inch) and a thickness of about 500 μm each. The seed were placed in a crystallisation zone of the autoclave.

Then, the autoclave was filled with ammonia (5N) in the amount of 191 g (about 11.2 mol), closed and introduced to a set of furnaces.

The dissolution zone was heated at a rate of about 0.5° C./min) to 450° C. At this time, the crystallisation zone was not heated. After reaching, in the dissolution zone, a predetermined temperature of 450° C., i.e. after about 15 hours from the beginning of the process, the temperature in the crystallisation zone was about 170° C. This temperature distribution had been maintained in the autoclave for 4 days. At this time, a partial carrying of gallium to the solution and a complete conversion of undissolved gallium to polycrystalline GaN occurred. Then, the temperature in the crystallisation zone was raised (a rate of about 0.1° C./min) to 550° C., and the temperature in the dissolution zone remained unchanged. The pressure inside the autoclave was about 410 MPa. The result of this temperature distribution was emergence of convection between zones in the autoclave, and consequently—of chemical transport of gallium nitride from the (upper) dissolution zone to the (lower) crystallisation zone, where it was deposited on seed. The obtained temperature distribution (i.e. 450° C. in the dissolution zone and 550° C. in the crystallisation zone) was maintained for the next 56 days (to the end of the process).

As a result of the process, partial dissolution of the feedstock (i.e. polycrystalline GaN) in the dissolution zone and growth of monocrystalline gallium nitride on seed, (on each seed) about 1.75 mm (measured in the direction of c-axis of the monocrystal), occurred. As a result of this process, an n-type conductive material with a concentration of free electrons of 4.8×10¹⁸ cm⁻³ and with a resistivity of 2×10⁻² Ω cm was obtained. The concentration of oxygen, measured by secondary ion mass spectroscopy (SIMS), is 9.0×10¹⁸ cm⁻³, the concentration of Mg—9.5×10¹⁶ cm⁻³.

### Example 2

Obtaining of doped GaN (Ca:NH₃=0.005; Mg:NH₃=0.000005, K:NH₃=0.08)

In a high-pressure autoclave with a volume of 9300 cm³, in a dissolution zone, as the feedstock, 1.3 kg (about 16.3 mol) of polycrystalline GaN with the addition of 37.6 g of Ca (940 mmol) and 23 mg of Mg (0.9 mmol) was placed. Into the autoclave, 588 g (about 15 mol) of metallic potassium having a purity of 4N was also introduced.

As the seed, 60 plates of monocrystalline gallium nitride obtained by HVPE method or by crystallisation from supercritical ammonia-containing solution, oriented perpendicularly to c-axis of the monocrystal, with a diameter of about 50 mm (2 inches) and a thickness of about 1500 μm each. The seed were placed in a crystallisation zone of the autoclave.

Then, the autoclave was filled with ammonia (5N) in the amount of 3.2 kg (about 188 mol), closed and introduced to a set of furnaces.

The dissolution zone was heated (a rate of about 0.5° C./min) to 550° C. At this time, the dissolution zone was not heated. After reaching, in the dissolution zone, a predetermined temperature of 450° C., i.e. after about 15 hours from the beginning of the process, the temperature in the crystallisation zone was about 170° C. This temperature distribution had been maintained in the autoclave for 4 days. At this time, a partial carrying of gallium to the solution and a complete conversion of undissolved gallium to polycrystalline GaN occurred. Then, the temperature in the crystallisation zone was raised (a rate of about 0.1° C./min) to 550° C., and the temperature in the dissolution zone remained unchanged. The pressure inside the autoclave was about 410 MPa. The result of this temperature distribution was emergence of convection between zones in the autoclave, and consequently—of chemical transport of gallium nitride from the (upper) dissolution zone to the (lower) crystallisation zone, where it was deposited on seed. The obtained temperature distribution (i.e. 450° C. in the dissolution zone and 550° C. in the crystallisation zone) was maintained for the next 56 days (to the end of the process).

As a result of the process, a layer of GaN (on each seed) with a thickness of about 1.8 mm (measured in the direction of c-axis of the monocrystal) was obtained. A conductive material of n-type conductivity and with a resistivity of 5×10⁻² Ω cm and with a concentration of free electrons of 1.2×10¹⁸ cm⁻³ was obtained. The concentration of oxygen, measured by secondary ion mass spectroscopy (SIMS), is 9.4×10¹⁷ cm⁻³, the concentration of Mg—9.0×10¹⁶ cm⁻³.

### Example 3

Obtaining of doped GaN (Ca:NH₃=0.05, Mg:NH₃=0.000005, Na:NH₃=0.08)

The same procedure as in Example 2, with the exception that, as solid substrates, 1.1 kg of metallic Ga (16.3 mol), 376 g of Ca (about 9.4 mol), 23 mg of Mg (0.9 mmol), 345 g of Na (15 mol) were used.

As a result of the process, a layer of GaN (on each seed) with a thickness of about 1.6 mm (measured in the direction of c-axis of the monocrystal) was obtained. A conductive n-type material with a resistivity of 8×10⁻² Ω cm and with a concentration of electrons of 1.1×10¹⁸ cm⁻³ was obtained. The concentration of oxygen, measured by secondary ion mass spectroscopy (SIMS), is 1.3×10¹⁸ cm⁻³ (saturation of oxygen level together with the increasing concentration of Ca), the concentration of Mg −5×10¹⁶ cm⁻³.

### Example 4

Obtaining of doped GaN (Ca:NH₃=0.005, Mg:NH₃=0.00002, Na:NH₃=0.04)

The same procedure as in Example 1, with the exception that, as solid substrates, 89.8 g of metallic Ga (1.29 mol), 2.25 g of Ca (56.2 mmol), 5.4 mg of Mg (about 0.22 mmol), 10.4 g of Na (0.45 mol) were used.

As a result of the process, a layer of GaN (on each seed) with a thickness of about 1.73 mm (measured in the direction of c-axis of the monocrystal) was obtained. A highly resistive material with a resistivity of >10⁶ Ω cm was obtained. The concentration of oxygen, measured by secondary ion mass spectroscopy (SIMS), is 8.2×10¹⁷ cm⁻³, the concentration of Mg −1.1×10¹⁸ cm⁻³.

### Example 5

Obtaining of doped GaN (Ca:NH₃=0.005, Mg:NH₃=0.00005, Na:NH₃=0.04)

The same procedure as in Example 1, with the exception that, as solid substrates, 89.8 g of metallic Ga (1.29 mol), 2.25 g of Ca (56.2 mmol), 13 mg of Mg (about 0.56 mmol), 10.4 g of Na (0.45 mol) were used.

As a result of the process, a layer of GaN (on each seed) with a thickness of about 1.79 mm (measured in the direction of axis c of the monocrystal) was obtained. A material of p-type conductivity and with a concentration of carriers (free holes) of 3×10¹⁶ cm⁻³ and with a resistivity of 2×10¹ Ω cm was obtained. The concentration of oxygen, measured by secondary ion mass spectroscopy (SIMS), is 1.3×10¹⁸ cm⁻³, the concentration of Mg −5×10¹⁸ cm⁻³.

### Example 6

Obtaining of doped GaN (Ca:NH₃=0.005; Mg:NH₃=0.0002, K:NH₃=0.12)

The same procedure as in Example 1, with the exception that, as solid substrates, 107.8 g of polycrystalline GaN (1.3 mol), 2.25 g of Ca (56.2 mmol), 0.05 g of Mg (about 2.25 mmol), 52.7 g of K (1.3 mol) were used.

As a result of the process, a layer of GaN (on each seed) with a thickness of about 1.7 mm (measured in the direction of c-axis of the monocrystal) was obtained. A material of p-type conductivity and with a concentration of carriers (free holes) of 1.8×10¹⁷ cm⁻³ and with a resistivity of 7×10¹ Ω cm was obtained. The concentration of oxygen, measured by secondary ion mass spectroscopy (SIMS), is 1.5×10¹⁸ cm⁻³, the concentration of Mg −8×10¹⁸ cm⁻³.

### Example 7

Obtaining of doped GaN (Gd:NH₃=0.001, Mg:NH₃=0.000005, Na:NH₃=0.04)

The same procedure as in Example 1, with the exception that, as solid substrates, 89.8 g of metallic Ga (1.3 mol), 1.8 g of Gd (11.2 mmol), 1.3 mg of Mg (about 0.056 mmol), 10.3 g of Na (0.45 mol) were used.

As a result of the process, a layer of GaN (on each seed) with a thickness of about 1.9 mm (measured in the direction of c-axis of the monocrystal) was obtained. An n-type conductive material with a concentration of free electrons of 2×10¹⁷ cm⁻³ and with a resistivity of 6×10⁻² Ω cm was obtained. The concentration of oxygen, measured by secondary ion mass spectroscopy (SIMS), is 1.2×10¹⁸ cm⁻³, the concentration of Mg −5×10¹⁷ cm⁻³.

### Example 8

Obtaining of doped GaN (Gd:NH₃=0.001, Mg:NH₃=0.00002, K:NH₃=0.08)

The same procedure as in Example 1, with the exception that, as solid substrates, 107.8 g of polycrystalline GaN (1.3 mol), 1.8 g of Gd (11.2 mmol), 5 mg of Mg (about 0.22 mmol) and 35.2 g of K (0.9 mol) were used.

As a result of the process, a layer of GaN (on each seed) with a thickness of about 1.6 mm (measured in the direction of c-axis of the monocrystal) was obtained. A highly resistive material with a resistivity of >1×10⁶ Ω cm was obtained. The concentration of oxygen, measured by secondary ion mass spectroscopy (SIMS), is 8×10¹⁷ cm⁻³, the concentration of Mg −1.2×10¹⁸ cm⁻³.

### Example 9

Obtaining of doped GaN (Gd:NH₃=0.0075; Ca:NH₃=0.0025; Mg:NH₃=0.00015; Zn:NH₃=0.00005; K:NH₃=0.12)

The same procedure as in Example 1, with the exception that, as solid substrates, 107.8 g of polycrystalline GaN (1.3 mol), 13.2 g of Gd (84.3 mmol), 1.1 g of Ca (28.1 mmol), 41 mg of Mg (about 1.7 mmol), 36 mg of Zn (0.56 mmol) and 52.7 g of K (1.35 mol) were used.

As a result of the process, a layer of GaN (on each seed) with a thickness of about 1.65 mm (measured in the direction of c-axis of the monocrystal) was obtained. A p-type material with a resistivity of 1.5×10¹ Ω cm and with a concentration of carriers (free holes) of 7×10¹⁶ cm⁻³ was obtained. The concentration of oxygen, measured by secondary ion mass spectroscopy (SIMS), is 9×10¹⁷ cm⁻³, the concentration of Mg −4.5×10¹⁸ cm⁻³, and the concentration of Zn −1.5×10¹⁸ cm⁻³.

### Example 10

Obtaining of doped GaN (Gd:NH₃=0.001; Zn:NH₃=0.000005; Na:NH₃=0.04)

The same procedure as in Example 2, with the exception that, as solid substrates, 1.1 kg of metallic Ga (16.3 mol), 29.5 g of Gd (188 mmol) and 61 mg of Zn (about 0.9 mmol), and 173 g of Na (7.5 mol) were used.

As a result of the process, a layer of GaN (on each seed) with a thickness of about 1.72 mm (measured in the direction of c-axis of the monocrystal) was obtained. An n-type material with a concentration of free electrons of 6×10¹⁷ cm⁻³, with a resistivity of 3×10⁻² Ω cm was obtained. The concentration of oxygen, measured by secondary ion mass spectroscopy (SIMS), is 1.1×10¹⁸ cm⁻³, the concentration of Zn −1.2×10¹⁷ cm⁻³.

### Example 11

Obtaining of doped GaN (Gd:NH₃=0.0075; Y:NH₃=0.0025; Zn:NH₃=0.00002; K:NH₃=0.04)

The same procedure as in Example 1, with the exception that, as solid substrates, 107.8 g of polycrystalline GaN (1.3 mol), 13.2 g of Gd (about 84.3 mmol), 2.5 g of Y (about 28.1 mmol), 14 mg of Zn (0.22 mmol) and 17.6 g of K (0.45 mmol) were used.

As a result of the process, a layer of GaN (on each seed) with a thickness of about 1.8 mm (measured in the direction of c-axis of the monocrystal) was obtained. An n-type material with a concentration of free electrons of 1×10¹⁷ cm⁻³, with a resistivity of 8×10⁻² Ω cm was obtained. The concentration of oxygen, measured by secondary ion mass spectroscopy (SIMS), is 9×10¹⁷ cm⁻³, the concentration of Zn−6×10¹⁷ cm⁻³.

### Example 12

Obtaining of doped GaN (Gd:NH₃=0.001; Zn:NH₃=0.00005; Na:NH₃=0.08)

The same procedure as in Example 1, with the exception that, as solid substrates, 89.8 g of metallic Ga (1.3 mol), 1.8 g of Gd (11.2 mmol), 36 mg of Zn (about 0.5 mmol), and 20.6 g of Na (0.9 mol) were used.

As a result of the process, a layer of GaN (on each seed) with a thickness of about 1.76 mm (measured in the direction of c-axis of the monocrystal) was obtained. A highly resistive material with a resistivity of >10⁶ Ω cm was obtained. The concentration of oxygen, measured by secondary ion mass spectroscopy (SIMS), is 9.8×10¹⁷ cm⁻³, the concentration of Zn −1.2×10¹⁸ cm⁻³.

### Example 13

Obtaining of doped GaN (Gd:NH₃=0.001; Zn:NH₃=0.0002; Na:NH₃=0.08)

The same procedure as in Example 1, with the exception that, as solid substrates, 107.8 g of polycrystalline GaN (1.3 mol), 1.8 g of Gd (11.2 mmol), 0.14 g of Zn (about 2.2 mmol) and 20.6 g of Na (0.9 mol) were used.

As a result of the process, a layer of GaN (on each seed) with a thickness of about 1.68 mm (measured in the direction of c-axis of the monocrystal) was obtained. A p-type material with a concentration of free carriers (holes) of 1×10¹⁶ cm⁻³ and with a resistivity of 2×10² Ω cm was obtained. The concentration of oxygen, measured by secondary ion mass spectroscopy (SIMS), is 8.2×10¹⁷ cm⁻³, the concentration of Zn−4.2×10¹⁸ cm⁻³.

### Example 14

Obtaining of doped GaN (Y:NH₃=0.01; Zn:NH₃=0.000005, K:NH₃=0.04)

The same procedure as in Example 2, with the exception that, as solid substrates, 1.1 kg of metallic Ga (16.3 mol), 167 g of yttrium (Y) (1.9 mol), 60 mg of Zn (0.9 mmol) and 294 g (7.5 mol) of K were used.

As a result of the process, a layer of GaN (on each seed) with a thickness of about 1.8 mm (measured in the direction of c-axis of the monocrystal) was obtained. An n-type material with a concentration of free carriers (electrons) of 2.3×10¹⁸ cm⁻³ and with a resistivity of 8×10⁻² Ω cm was obtained. The concentration of oxygen, measured by secondary ion mass spectroscopy (SIMS), is 3×10¹⁸ cm⁻³, the concentration of Zn−2.1×10¹⁷ cm⁻³.

### Example 15

Obtaining of doped GaN (Y:NH₃=0.01; Zn:NH₃=0.00005, Na:NH₃=0.08)

The same procedure as in Example 1, with the exception that, as solid substrates, 89.8 g of metallic Ga (1.3 mol), 10 g of yttrium (Y) (112 mmol), 36 mg of Zn (0.56 mmol), 20.7 g of Na (0.9 mol) were used.

As a result of the process, a layer of GaN (on each seed) with a thickness of about 1.7 mm (measured in the direction of c-axis of the monocrystal) was obtained. A highly resistive material with a resistivity of >10⁶ Ω cm was obtained. The concentration of oxygen, measured by secondary ion mass spectroscopy (SIMS), is 3.2×10¹⁸ cm⁻³, the concentration of Zn−4×10¹⁸ cm⁻³.

### Example 16

Obtaining of doped GaN (Y:NH₃=0.01; Zn:NH₃=0.00015; Mg:NH₃=0.00005; K:NH₃=0.12)

The same procedure as in Example 1, with the exception that, as solid substrates, 89.8 g of metallic Ga (1.3 mol), 10 g of yttrium (Y) (112 mmol), 0.11 g of Zn (1.7 mmol), 14 mg of Mg (0.56 mmol), 52.7 g of K were used.

As a result of the process, a layer of GaN (on each seed) with a thickness of about 1.75 mm (measured in the direction of c-axis of the monocrystal) was obtained. A p-type material with a concentration of free carriers (holes) of 2×10¹⁶ cm⁻³ and with a resistivity of 3×10¹ Ω cm was obtained. The concentration of oxygen, measured by secondary ion mass spectroscopy (SIMS),is 2.5×10¹⁸ cm⁻³, the concentration of Zn−5.7×10¹⁸ cm⁻³, and the concentration of Mg −1.8×10¹⁸ cm⁻³.

1. A method for obtaining monocrystalline gallium-containing nitride from gallium-containing feedstock, in the environment of supercritical ammonia-containing solvent with the addition of a mineraliser, containing an element of Group I (IUPAC, 1989), wherein, in an autoclave, two temperature zones are generated, i.e. a dissolution zone of lower temperature, containing feedstock, and, below it, a crystallisation zone of higher temperature, containing at least one seed a dissolution process of the feedstock and a crystallisation process of the gallium-containing nitride on the at least one seed are carried out, characterised in that at least two additional components are introduced into the process environment, namely:
a) an oxygen getter in a molar ratio to ammonia ranging from 0.0001 to 0.2;
b) an acceptor dopant in a molar ratio to ammonia not higher than 0.001.

2. The method according to claim 1, where the oxygen getter is introduced in a molar ratio to ammonia ranging from 0.0005 to 0.05.

3. The method according to claim 1 where the oxygen getter is constituted by calcium or a rare earth element, preferably gadolinium or yttrium, or a combination thereof.

4. The method according to claim 1, where the acceptor dopant is constituted by magnesium, zinc, cadmium or beryllium, or a combination thereof.

5. The method according to claim 1, where the oxygen getter and the acceptor dopant are introduced in the elemental form, i.e. in the form of metal, or in the form of compound, preferably from the group comprising azides, amides, imides, amidoimides and hydrides, wherein these components are introduced separately or in combination, and in the case of introducing them in combination, mixtures of elements or compounds, intermetallic compounds or alloys, are used.

6. The method according to claim 1, where the oxygen getter and/or the acceptor dopant are introduced into the process environment together with the mineraliser.

7. The method according to claim 1, where the mineraliser contains sodium or potassium, in a molar ratio to ammonia ranging from 0.005 to 0.5.

8. The method according to claim 1, where a stoichiometric gallium nitride, GaN, is obtained.

9. The method according to claim 1, where it is carried out in an autoclave having an internal volume higher than 600 cm³, more preferably higher than 9000 cm³.

10. The monocrvstalline gallium-containing nitride, obtained by the method of claim 1, containing at least one element of Group I (IUPAC, 1989) in an amount of at least 0.1 ppm, it contains oxygen in a concentration not higher than 1×10¹⁹ cm⁻³, preferably not higher than 3×10¹⁸ cm⁻³, and most preferably not higher than 1×10¹⁸ cm⁻³.

11. The nitride according to claim 10, characterised in that it is an n-type conductive material.

12. The nitride according to claim 11, characterised in that it contains acceptors selected from magnesium, zinc, cadmium or beryllium with a total concentration not higher than 1×10¹⁸ cm⁻³, more preferably not higher than 3×10¹⁷ cm⁻³, most preferably not higher than 1×10¹⁷ cm⁻³, wherein the ratio of oxygen concentration to the total concentration of acceptors being not lower than 1.2.

13. The nitride according to claim 11, where it exhibits a concentration of carriers (free electrons) not higher than 7×10¹⁸ cm⁻³, more preferably not higher than 2×10¹⁸ cm⁻³, and most preferably not higher than 7×10¹⁷ cm⁻³.

14. The nitride according to claim 10, characterised in that it is a p-type conductive material.

15. The nitride according to claim 14, characterised in that it contains acceptors selected from magnesium, zinc, cadmium or beryllium with a total concentration not higher than 2×10¹⁹ cm⁻³, more preferably not higher than 6×10¹⁸ cm⁻³, most preferably not higher than 2×10¹⁸ cm⁻³, wherein the ratio of oxygen concentration to the total concentration of acceptors being not higher than 0.5.

16. The nitride according to claim 14, where it exhibits a concentration of carriers (free holes) lower than 5×10¹⁷ cm⁻³.

17. The nitride according to claim 10, characterised in that it is a highly resistive (semi-insulating) material.

18. The nitride according to claim 17, where it contains acceptors selected from magnesium, zinc, cadmium or beryllium with a total concentration not higher than 1×10¹⁹ cm⁻³, more preferably not higher than 3×10¹⁸ cm⁻³, most preferably not higher than 1×10¹⁸ cm⁻³, the ratio of oxygen concentration to the total concentration of acceptors ranging from 0.5 to 1.2.

19. The nitride according to claim 17, where it has a resistivity higher than 1×10⁵ Ω cm, more preferably higher than 1×10⁶ Ω cm, and most preferably higher than 1×10⁹ Ω cm.

20. The nitride according to claim 1, where it is a stoichiometric gallium nitride GaN.
